(19) United States
(12) Patent Application Publication
(10) Pub. No.: US 2014/0353594 A1
(43) Pub. Date: Dec. 4, 2014

(54) OLED Panel, Manufacturing Method, and Related Testing Method

(71) Applicant: Shenzhen China Star Optoelectronics Technology Co., Ltd., Shenzhen, Guangdong (CN)

(72) Inventor: Weijing Zeng, Shenzhen (CN)

(73) Assignee: Shenzhen China Star Optoelectronics Technology Co., Ltd., Shenzhen, Guangdong (CN)

(21) Appl. No.: 13/985,910

(22) PCT Filed: Jun. 28, 2013
(86) PCT No.: PCT/CN2013/078254

§ 371 Date: Aug. 16, 2013

(30) Foreign Application Priority Data
May 29, 2013 (CN) 201310206457.3

(51) Int. Cl. H01L 27/32; H01L 21/66; H01L 51/56

(52) U.S. Cl. CPC H01L 27/3225; H01L 51/56; H01L 22/12; H01L 22/30
USPC 257/40; 438/25; 438/15

(57) ABSTRACT

The present invention discloses an OLED panel, a manufacturing method and related testing method. The OLED panel includes a substrate (20), a cover (40) positioned oppositely to the substrate (20), an OLED device positioned on the substrate (20), a humidity sensing film (42) positioned on the cover (40), a sealed frame (60) for adhering the substrate (20) and the cover (40), a plurality of testing wires between the humidity sensing film (42) and the cover (40), wherein one end of each of the testing wires is electrically connected to the humidity sensing film (42); wherein the substrate (20), the cover (40), and the sealed frame (246) form a sealed space, the OLED device and the humidity sensing film (42) are inside the sealed space, and another end of each of the testing wires stretches to an outside of the sealed space (246).

### BACKGROUND OF THE INVENTION

1. Field of the Invention

The invention relates to a flat display, and more particularly, to an OLED panel, related manufacturing method, and related testing method for testing its packaging effect.

2. Description of the Prior Art

Flat displays are widely used because they're thin and low power consuming without any radiation. The flat displays include liquid crystal displays (LCD) and organic light emitting displays (OLED).

The OLED displays have characteristics of self-lighting, high-luminance, wide view angle, high contrast, bendable figure, low power consumption. Therefore, OLED displays are regarded as a new generation of displays, and gradually replace the traditional LCD displays. The OLED displays are widely utilized as cell phone screens, computer monitors, and TV screens. The display mechanisms of the OLED and LCD are different. OLED displays do not need any backlight module, instead, OLED displays adopt very thin organic material coating layer and glass substrate. When there are currents flowing through, the organic material generates lights. However, the organic material is easy to be acted with water and oxygen. Therefore, packaging requirements of the OLED displays are very restricted. In order for mass production, the life time of the OLED devices should be not less than 10000 hours. To meet the above-mentioned life time requirement, the packaging effect has to achieve that the water puncture rate should be less than or equal to 10⁻⁶ g/m²/day and the oxygen puncture rate should be less than or equal to 10⁻⁵ cc/m²/day (under 1 atm). It can be seen that the packaging procedure is the key point of the entire manufacturing procedure and also key point of the product yield.

However, according to the current OLED panel manufacturing procedure, very few testing method for testing the packaging effect are introduced. A testing method which utilizes a desiccant to monitor the packaging effect is introduced. The basic theory of this method is: the desiccant absorbs humidity and then expands. Therefore, as long as a camera is utilized to record the square measure of the desiccants, the square measure can be monitored to see if the desiccant expands or not. In this way, we can know whether the OLED panel is packaged well enough to block the vapor to go in. This method is quite simple, but reliability problem exists. For example, the volume of the desiccant expands because it absorbs water, but the camera can only respond to the difference of the square measure. Furthermore, through compare the photos taken by the camera cannot reflect to a tiny volume difference. Therefore, this testing method is not good enough and should be improved.

In order to solve the above-mentioned problem, another testing method is introduced. Please refer to FIG. 1, a testing wire 4 is positioned inside a sealed cavity 11 formed by a substrate 1, a cover 2, and a sealed layer 3. In addition, a light emitting chip 9 is positioned on the substrate 1 inside the sealed cavity 11. The testing wire 4 is positioned on the cover 2 and opposite to the light emitting chip 9. Testing electrodes 5 are respectively positioned on two ends of the testing wire 4. One end of the testing electrode 5 is electrically connected to the testing wire 4 and the other end of the testing electrode 5 stretches out to the outside of the sealed cavity 11. In general, the testing wire 4 is manufactured with calcium, barium, or other metal which can be easily oxidized. According to the variance of the resistance rate of the testing wire 4, the sealing effect of the sealed cavity 11 can be determined. Generally speaking, the variance of the resistance is larger, the testing effect is more obvious.

The above-mentioned testing method can test the packaging effect of OLED panel more efficiently, but the manufacturing procedure of the above-mentioned device is more complicated and costs more. Furthermore, in order to prevent the normal electrodes 10 and the testing electrodes 5 from interfering each other, an insulating layer 6 is positioned between the sealed layer 3 and the testing electrodes 5. This makes the entire structure of the OLED panel more complicated, and the manufacturing procedures become more complicated correspondingly.

### SUMMARY OF THE INVENTION

It is therefore one of the primary objectives of the claimed invention to provide a OLED panel, having better packaging effect and longer life time, in order to solve the above-mentioned problem.

Another objective of the claimed invention is to provide a manufacturing method for manufacturing an OLED panel. The manufacturing method is simple, can manufacture an OLED panel having a longer life time, and can effectively test its packaging effect to raise the yield.

Another objective of the claimed invention is to provide a testing method for testing the packaging effect of the OLED panel. The testing method can detect the contained water and oxygen inside the package of the OLED panel such that the packaging effect can be precisely determined. This testing method is easier to accomplish without any side effects on the panel.

According to an exemplary embodiment of the claimed invention, an organic light emitting diode (OLED) panel is disclosed. The OLED panel comprises a substrate, a cover positioned oppositely to the substrate, an OLED device positioned on the substrate, a humidity sensing film positioned on the cover, a sealed frame for adhering the substrate and the cover, and a plurality of testing wires between the humidity sensing film and the cover. One end of each of the testing wires is electrically connected to the humidity sensing film. The substrate, the cover, and the sealed frame form a sealed space. The OLED device and the humidity sensing film are inside the sealed space, and another end of each of the testing wires stretches to an outside of the sealed space via the sealed frame for being electrically connected to a testing device.

Furthermore, the humidity sensing film is manufactured with a conductive powder and a high molecular material having a characteristic of easily absorbing humidity to expand, and the conductive power is a carbon black powder.

Furthermore, the substrate is a glass substrate, and the sealed frame is manufactured with a fit glue or a UV glue.

According to an exemplary embodiment of the claimed invention, a manufacturing method for manufacturing an organic light emitting diode (OLED) panel is disclosed. The manufacturing method comprises: providing a cover, forming a testing wire on the cover, spreading a fit glue on a position near an edge of the cover and performing a high-temperature baking on the fit glue to form a sealed frame, wherein one end of the testing wire is inside the sealed frame, and another end of the testing wire is outside the sealed frame, forming a humidity sensing film inside the sealed frame on the cover and performing a low-temperature baking, spreading a bonding glue on the sealed frame, providing a substrate, wherein an OLED device is formed on the substrate, and fixing the substrate and the cover by using the bonding glue and solidifying the sealed frame. Please note, the humidity sensing film covers parts of the testing wire.

Furthermore, the humidity sensing film is manufactured with a conductive powder and a high molecular material having a characteristic of easily absorbing humidity to expand, the conductive power is a carbon black powder, and the bonding glue is a cofferdam glue.

According to an exemplary embodiment of the claimed invention, another manufacturing method for manufacturing an organic light emitting diode (OLED) panel is disclosed. The manufacturing method comprises: providing a cover, forming a testing wire on the cover, forming a humidity sensing film on the cover and performing a low-temperature baking, wherein the humidity sensing film covers parts of the testing wire, spreading a UV glue on a position near an edge of the cover to form a sealed frame, wherein the humidity sensing film is inside the sealed frame, one end of the testing wire is inside the sealed frame, and another end of the testing wire is outside the sealed frame, providing a substrate, wherein an OLED device is formed on the substrate; and fixing the substrate and the cover by using the UV glue and solidifying the sealed frame.

Furthermore, the humidity sensing film is manufactured with a conductive powder and a high molecular material having a characteristic of easily absorbing humidity to expand, and the conductive power is a carbon black powder.

According to an exemplary embodiment of the claimed invention, a testing method for testing a packaging effect of an organic light emitting diode (OLED) panel is disclosed. The testing method comprises: providing an OLED panel, comprising a substrate, a cover positioned oppositely to the substrate, an OLED device positioned on the substrate, a humidity sensing film positioned on the cover, a sealed frame for adhering the substrate and the cover, a plurality of testing wires between the humidity sensing film and the cover, wherein one end of each of the testing wires is electrically connected to the humidity sensing film, where the substrate, the cover, and the sealed frame form a sealed space, the OLED device and the humidity sensing film are inside the sealed space, and another end of each of the testing wires stretches to an outside of the sealed space. The testing method further comprises providing the testing device and electrically connecting the testing device to the another end of the testing wire such that the testing device is electrically connected to the humidity sensing film, and measuring a conductivity of the humidity sensing film and comparing the measured conductivity with a predetermined standard conductivity to determine the packaging effect.

Furthermore, the humidity sensing film is manufactured with a conductive powder and a high molecular material having a characteristic of easily absorbing humidity to expand, and the conductive power is a carbon black powder.

Furthermore, the standard conductivity is corresponding to a conductivity of the humidity sensing film under the condition that the humidity sensing film contains 1000 ppm water and 10⁶ ppm oxygen, and if the measured conductivity is larger than or equal to the standard conductivity, then the packaging effect is determined as qualified, otherwise, the packaging effect is determined as unqualified.

In contrast to the related art, the present invention provides an OLED panel, a manufacturing method, and a related testing method. The present invention utilizes a humidity sensing film, which is manufactured with a conductive powder and a high molecular material having a characteristic of easily absorbing humidity to expand. Therefore, this can be utilized as a desiccant to expand the life time of the OLED panel. Furthermore, this can also be utilized to detect the water and oxygen inside the OLED panel by measuring its conductivity. In this way, the packaging effect can be determined precisely. Furthermore, this manufacturing method is quite simple and easy to accomplish.

These and other objectives of the claimed invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification.

FIG. 1 is a diagram depicting a cross section of an OLED panel according to the related art.

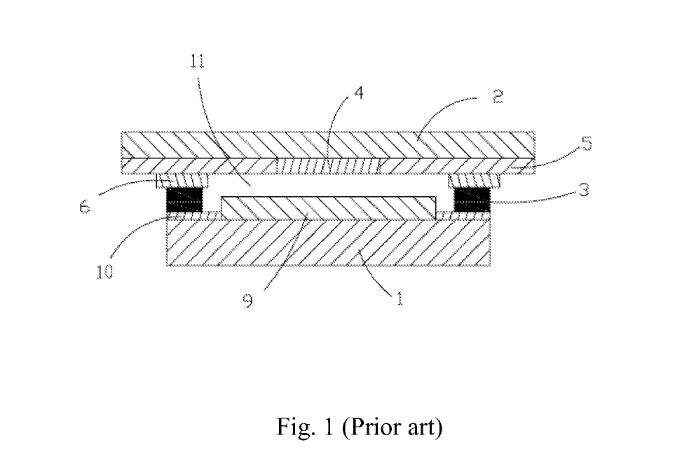

FIG. 2 is a diagram depicting a cross section of an OLED panel according to the present invention.

FIG. 3 is a diagram showing a flat structure of the cover where the testing wire, the humidity sensing film, and sealed frame are formed shown in FIG. 2.

FIG. 4 is a flow chart illustrating a manufacturing method for manufacturing an OLED panel according to a first embodiment of the present invention.

FIG. 5 is a flow chart illustrating a manufacturing method for manufacturing an OLED panel according to a second embodiment of the present invention.

FIG. 6 is a flow chart illustrating a testing method for testing a packaging effect of an OLED panel according to a second embodiment of the present invention.

### DETAILED DESCRIPTION OF THE PREFERRED EMBODIMENT

The drawings illustrate embodiments of the invention and, together with the description, serve to explain the principles of the invention.

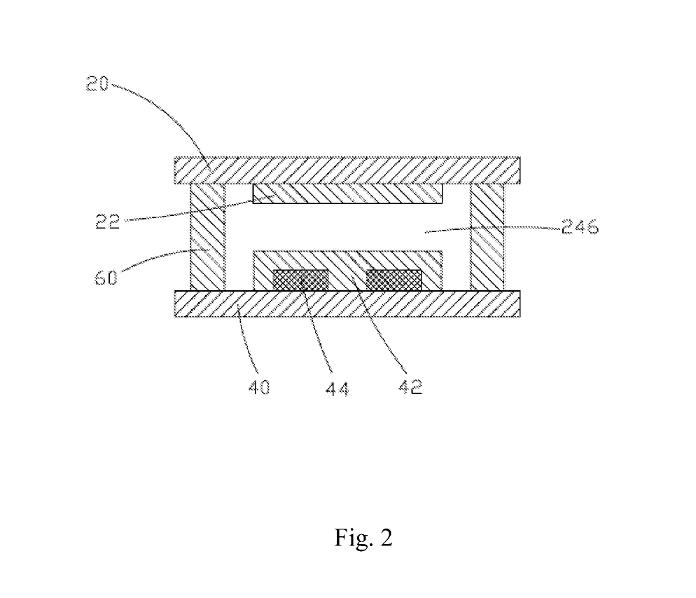

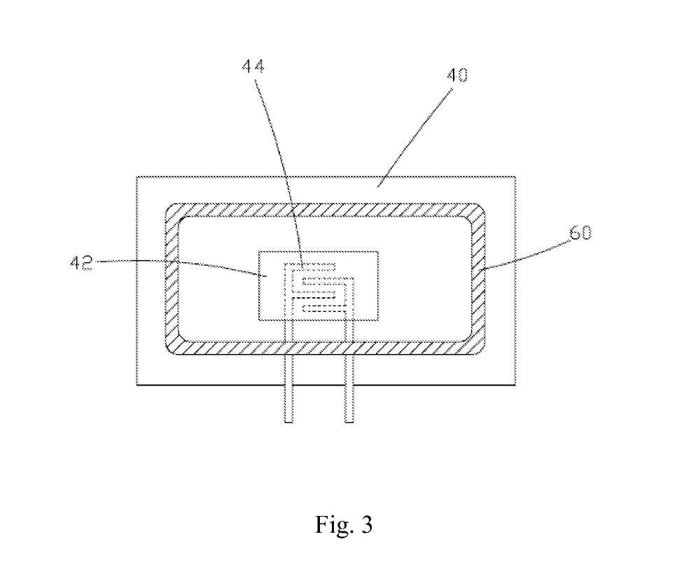

Please refer to FIG. 2 in conjunction with FIG. 3. An OLED panel is provided. The OLED panel comprises a substrate 20, a cover 40 positioned oppositely to the substrate 20, an OLED device 22 positioned on the substrate 20, a humidity sensing film 42 positioned on the cover 40, and a sealed frame 60 for adhering the substrate 20 and the cover 40. The substrate 20, the cover 40, and the sealed frame 60 form a sealed space 246. The OLED device 22 and the humidity sensing film 42 are both sealed inside the sealed space 246. A plurality of testing wires 44 are positioned between the humidity sensing film 42 and the cover 40. One end of each of the testing wires 44 is electrically connected to the humidity sensing film 42, and another end of each of the testing wires 44 stretches to an outside of the sealed space 246 via the sealed frame 60 for being electrically connected to a testing device.

The substrate 20 is a transparent substrate. Optimally, the substrate 20 is a glass substrate. The OLED device 22 generally comprises an anode, an organic layer formed on the anode, and a cathode formed on the organic layer. Please note, the organic layer often comprises a hole transport layer formed on the anode, an emitting material layer formed on the hole transport layer, an electron transport layer formed on the emitting material layer, where each of the layers can be formed through vacuum evaporation.

The humidity sensing film 42 is manufactured with a conductive powder and a high molecular material having a characteristic of easily absorbing humidity to expand. Optimally, the conductive power is a carbon black powder which has good conductivity. When the humidity sensing film 42 has not absorbed any humidity, the humidity sensing film 42 is in a shrinking state. In the shrinking state, the concentration of the conductive power is comparative high, and distance between particles of the conductive power is short. At this time, the resistance of the humidity sensing film 42 is low. When the temperature arises, the humidity sensing film 42 absorbs more water. This makes the volume of the humidity sensing film 42 increase and the distance between particles of the conductive power is larger. At this time, the resistance of the humidity sensing film 42 increases. Therefore, the conductivity of the humidity sensing film 42 can be monitored to determine the packaging effect of the OLED panel.

The testing wires 44 are formed on the cover 40 through vacuum evaporation. Please refer to FIG. 3, in this embodiment, the number of the testing wires 44 is two. One testing wire 44 is an “F” shape wire, and the other testing wire 44 is positioned oppositely. The two testing wires 44 are intercrossed in order to measure the conductivity of the humidity sensing film 42 more precisely.

The sealed frame 60 is manufactured with a frit glue or a UV glue.

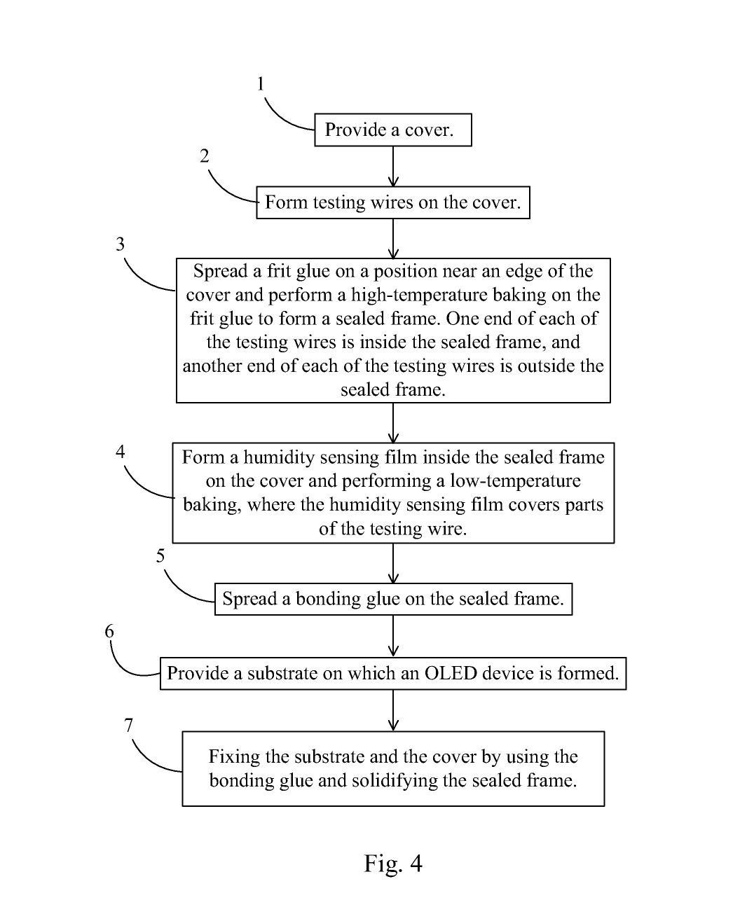

Please refer to FIG. 2 in conjunction with FIG. 3 and FIG. 4. A manufacturing method for manufacturing an OLED panel is disclosed. The manufacturing method comprises following steps:

Step 1: Provide a cover 40.

Step 2: Form testing wires 44 on the cover 40;

The testing wires 44 are formed on the cover 40 through vacuum evaporation. Please refer to FIG. 3, in this embodiment, the number of testing wires 44 is two. One testing wire 44 is an “F” shape wire, and the other testing wire 44 is positioned oppositely. The two testing wires 44 are intercrossed.

Step 3: Spread a frit glue on a position near an edge of the cover 40 and perform a high-temperature baking on the frit glue to form a sealed frame 60. One end of each of the testing wires 44 is inside the sealed frame 60, and another end of each of the testing wires is outside the sealed frame 60.

The frit glue is spread on a position near an edge of the cover 40. And then, a high-temperature baking is performed on the frit glue to half-solidify the frit glue such that the sealed frame 60 is formed.

The testing wire 44 stretches to the outside of the sealed frame 60 to be electrically connected to an external testing device. In this way, in the following testing procedure, the conductivity of the humidity sensing film 42 can be monitored.

Step 4: Form a humidity sensing film 42 inside the sealed frame 60 on the cover 40 and performing a low-temperature baking, where the humidity sensing film 42 covers parts of the testing wire 44.

The humidity sensing film 42 is manufactured with a conductive powder and a high molecular material having a characteristic of easily absorbing humidity to expand. Optimally, the conductive power is a carbon black powder which has good conductivity. When the humidity sensing film 42 has not absorbed any humidity, the humidity sensing film 42 is in a shrinking state. In the shrinking state, the concentration of the conductive power is comparative high, and distance between particles of the conductive power is short. At this time, the resistance of the humidity sensing film 42 is low. When the temperature arises, the humidity sensing film 42 absorbs more water. This makes the volume of the humidity sensing film 42 increase and the distance between particles of the conductive power is larger. At this time, the resistance of the humidity sensing film 42 increases. Therefore, the conductivity of the humidity sensing film 42 can be monitored to determine the packaging effect of the OLED panel.

Please note, because the humidity sensing film 42 is sensitive to temperature. After the humidity sensing film 42 is formed on the cover 40, a low-temperature baking is performed on it to ensure the dryness.

Step 5: Spread a bonding glue on the sealed frame 60.

In this embodiment, optimally, the bonding glue is the cofferdam glue (DAM glue) to efficiently raises the sealing effect.

Step 6: Provide a substrate 20. An OLED device 22 is formed on the substrate 20.

The substrate 20 is a transparent substrate. Optimally, the substrate 20 is a glass substrate. The OLED device 22 generally comprises an anode, an organic layer formed on the anode, and a cathode formed on the organic layer. Please note, the organic layer often comprises a hole transport layer formed on the anode, an emitting material layer formed on the hole transport layer, an electron transport layer formed on the emitting material layer, where each of the layers can be formed through vacuum evaporation.

Step 7: Fixing the substrate 20 and the cover 40 by using the bonding glue and solidifying the sealed frame 60.

The substrate 20 and the cover 40 are pasted together. And the sealed frame 60 is solidified to seal the OLED device 22 and the humidity sensing film 42 inside the sealed space 246 formed by the substrate 20, the cover 40 and the sealed frame 60.

The solidification will be illustrated as follows. First, UV lights are utilized to light up the DAM glue to solidify the DAM glue. And then, the laser sealing is performed to solidify the frit glue.

The OLED panel manufactured by the above-mentioned manufacturing method has a longer life time. Furthermore, the packaging effect can be effectively tested to raise the yield.

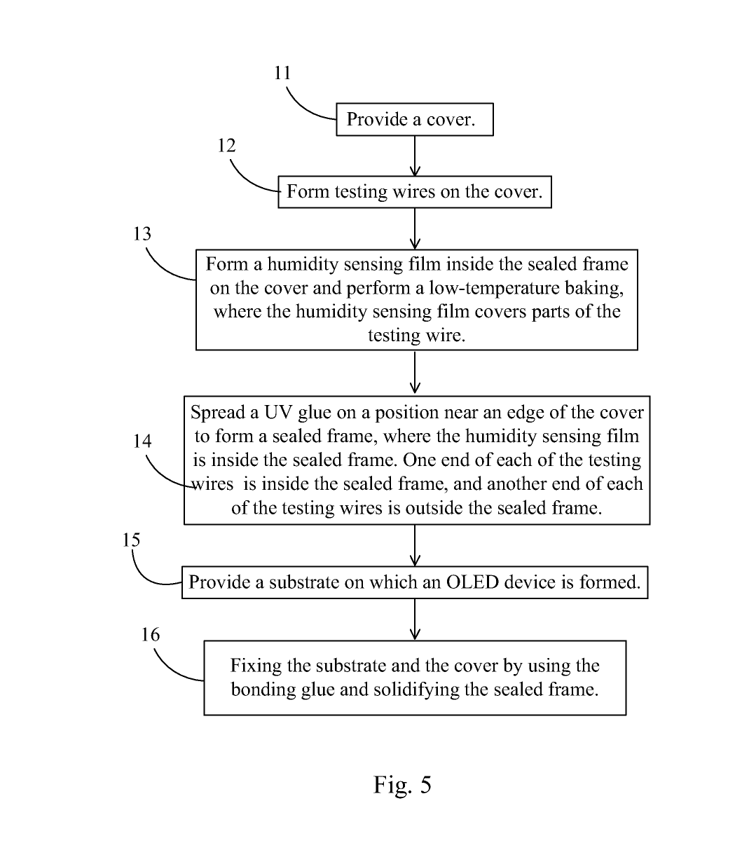

Please refer to FIG. 5 in conjunction with FIG. 2 and FIG. 3. Another manufacturing method for manufacturing an OLED panel is disclosed. The manufacturing method comprises following steps:

Step 11: Provide a cover 40.

Step 12: Form testing wires 44 on the cover 44;

The testing wires 44 are formed on the cover 40 through vacuum evaporation. Please refer to FIG. 4, in this embodiment, the number of testing wires 44 is two. One testing wire 44 is an “F” shape wire, and the other testing wire 44 is positioned oppositely. The two testing wires 44 are intercrossed.

Step 13: Form a humidity sensing film 42 on the cover 40 and perform a low-temperature baking, where the humidity sensing film 42 covers parts of the testing wires 44.

The humidity sensing film 42 is manufactured with a conductive powder and a high molecular material having a characteristic of easily absorbing humidity to expand. Optimally, the conductive power is a carbon black powder which has good conductivity. When the humidity sensing film 42 has not absorbed any humidity, the humidity sensing film 42 is in a shrinking state. In the shrinking state, the concentration of the conductive power is comparative high, and distance between particles of the conductive power is short. At this time, the resistance of the humidity sensing film 42 is low. When the temperature arises, the humidity sensing film 42 absorbs more water. This makes the volume of the humidity sensing film 42 increase and the distance between particles of the conductive power is larger. At this time, the resistance of the humidity sensing film 42 increases. Therefore, the conductivity of the humidity sensing film 42 can be monitored to determine the packaging effect of the OLED panel.

Please note, because the humidity sensing film 42 is sensitive to temperature. After the humidity sensing film 42 is formed on the cover 40, a low-temperature baking is performed on it to ensure the dryness.

In this embodiment, the humidity sensing film 42 covers an upper part of the testing wires 44 and reserve a certain space to form the sealed frame 60.

Step 14: Spread a UV glue on a position near an edge of the cover 40 to form a sealed frame 60, where the humidity sensing film 42 is inside the sealed frame 60, one end of each of the testing wires 44 is inside the sealed frame 60, and another end of each of the testing wires 44 is outside the sealed frame 60.

The testing wire 44 stretches to the outside of the sealed frame 60 to be electrically connected to an external testing device. In this way, in the following testing procedure, the conductivity of the humidity sensing film 42 can be monitored.

Step 15: Provide a substrate 20, where an OLED device 22 is formed on the substrate.

The substrate 20 is a transparent substrate. Optimally, the substrate 20 is a glass substrate. The OLED device 22 generally comprises an anode, an organic layer formed on the anode, and a cathode formed on the organic layer. Please note, the organic layer often comprises a hole transport layer formed on the anode, an emitting material layer formed on the hole transport layer, an electron transport layer formed on the emitting material layer, where each of the layers can be formed through vacuum evaporation.

Step 16: Fix the substrate 20 and the cover 40 by using the UV glue and solidifying the sealed frame 60.

The substrate 20 and the cover 40 are pasted together. And the sealed frame 60 is solidified to seal the OLED device 22 and the humidity sensing film 42 inside the sealed space 246 formed by the substrate 20, the cover 40 and the sealed frame 60.

The solidification is accomplished by utilizing UV lights to light up the UV glue such that the sealed frame 60 is solidified.

The OLED panel manufactured by the above-mentioned manufacturing method has a longer life time. Furthermore, the packaging effect can be effectively tested to raise the yield.

After the OLED panel is packaged, the sealed space should be tested to guarantee the life time of the OLED panel. Currently, the OLED panel is required to have a life time larger than or equal to 10000 hours. To meet that demand, the packaged OLED panel should comply with following criteria. First, the water puncture rate of the packaged OLED panel should be less than or equal to 10⁻⁶ g/m²/day. Second, the oxygen puncture rate of the packaged OLED panel should be less than or equal to 10⁻⁵ cc/m²/day (under 1 atm). Under the aforementioned condition, it can be evaluated that the water contained inside the sealed space should not be larger than 1000 ppm, and the oxygen contained inside the sealed space should not be larger than 10⁶ ppm. From the above, it can be seen that the amount of the water and oxygen contained inside the sealed space can be a testing standard to determine whether the OLED panel is qualified or not qualified. Therefore, a testing method is provided. The testing method is used to detect the water and oxygen amount inside the sealed space of the OLED panel to determine whether the OLED panel is qualified or not.

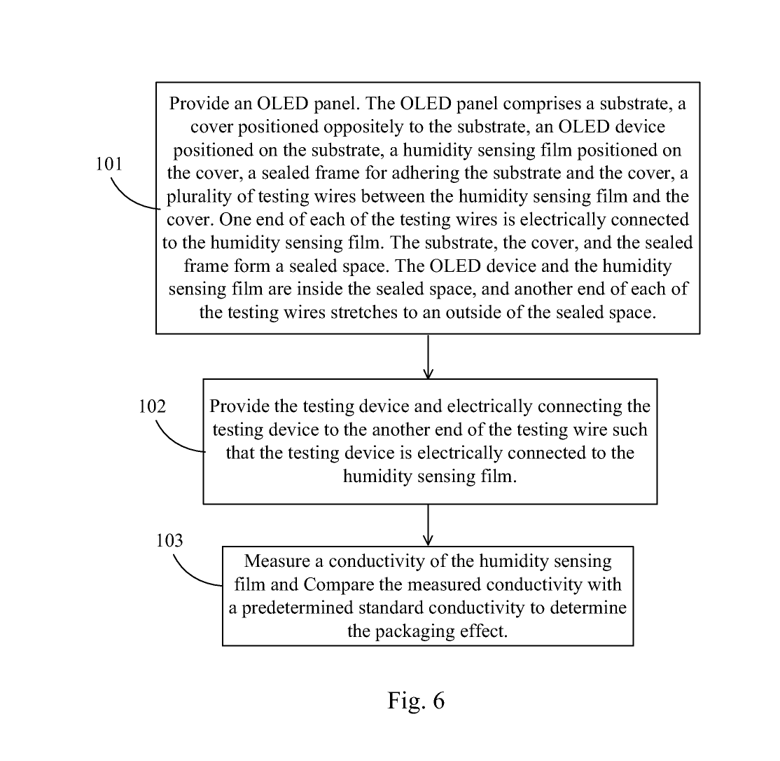

Please refer to FIG. 6 in conjunction with FIG. 2 and FIG. 3. A testing method for testing the packaging effect of an OLED panel is disclosed. The testing method comprises following steps:

Step 101: Provide an OLED panel. The OLED panel comprises a substrate 20, a cover 40 positioned oppositely to the substrate 20, an OLED device 22 positioned on the substrate 20, a humidity sensing film 42 positioned on the cover 40, a sealed frame 60 for adhering the substrate 20 and the cover 40, a plurality of testing wires 44 between the humidity sensing film 42 and the cover 40, wherein one end of each of the testing wires 44 is electrically connected to the humidity sensing film 42, wherein the substrate 20, the cover 40, and the sealed frame 60 form a sealed space 246, the OLED device 22 and the humidity sensing film 42 are inside the sealed space 246, and another end of each of the testing wires 44 stretches to an outside of the sealed space 246.

The substrate 20 is a transparent substrate. Optimally, the substrate 20 is a glass substrate. The OLED device 22 generally comprises an anode, an organic layer formed on the anode, and a cathode formed on the organic layer. Please note, the organic layer often comprises a hole transport layer formed on the anode, an emitting material layer formed on the hole transport layer, an electron transport layer formed on the emitting material layer, where each of the layers can be formed through vacuum evaporation.

The humidity sensing film 42 is manufactured with a conductive powder and a high molecular material having a characteristic of easily absorbing humidity to expand. Optimally, the conductive power is a carbon black powder which has good conductivity. When the humidity sensing film 42 has not absorbed any humidity, the humidity sensing film 42 is in a shrinking state. In the shrinking state, the concentration of the conductive power is comparative high, and distance between particles of the conductive power is short. At this time, the resistance of the humidity sensing film 42 is low. When the temperature arises, the humidity sensing film 42 absorbs more water. This makes the volume of the humidity sensing film 42 increase and the distance between particles of the conductive power is larger. At this time, the resistance of the humidity sensing film 42 increases. Therefore, the conductivity of the humidity sensing film 42 can be monitored to determine the packaging effect of the OLED panel.

The testing wires 44 are formed on the cover 40 through vacuum evaporation. Please refer to FIG. 3, in this embodiment, the number of the testing wires 44 is two. One testing wire 44 is an “F” shape wire, and the other testing wire 44 is positioned oppositely. The two testing wires 44 are intercrossed in order to measure the conductivity of the humidity sensing film 42 more precisely.

The sealed frame 60 is formed with a fit glue or a UV glue.

Step 102: Provide the testing device and electrically connect the testing device to another end of each of the testing wires such that the testing device is electrically connected to the humidity sensing film.

Step 103: Measure a conductivity of the humidity sensing film and compare the measured conductivity with a predetermined standard conductivity to determine the packaging effect.

The above-mentioned standard conductivity is corresponding to a conductivity of the humidity sensing film under the condition that the humidity sensing film contains 1000 ppm water and 10⁶ ppm oxygen. If the measured conductivity is larger than or equal to the standard conductivity, it means that the water contained inside the sealed space 246 is less than or equal to 1000 ppm and oxygen contained inside the sealed space 246 is less than or equal to 10⁶ ppm. So the packaging effect is determined as qualified. Otherwise, if the measured conductivity is less than the standard conductivity, it means that the water contained inside the sealed space 246 is larger than 1000 ppm and oxygen contained inside the sealed space 246 is larger than 10⁶ ppm. So the packaging effect is determined as not qualified.

From the above, the present invention provides an OLED panel, a manufacturing method, and a related testing method. The present invention utilizes a humidity sensing film, which is manufactured with a conductive powder and a high molecular material having a characteristic of easily absorbing humidity to expand. Therefore, this can be utilized as a desiccant to expand the life time of the OLED panel. Furthermore, this can also be utilized to detect the water and oxygen inside the OLED panel by measuring its conductivity. In this way, the packaging effect can be determined precisely. Furthermore, this manufacturing method is quite simple and easy to accomplish.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. An organic light emitting diode (OLED) panel, comprising:
a substrate;
a cover, positioned oppositely to the substrate;
an OLED device, positioned on the substrate;
a humidity sensing film, positioned on the cover;
a sealed frame, for adhering the substrate and the cover; and
a plurality of testing wires, between the humidity sensing film and the cover, one end of each of the testing wires being electrically connected to the humidity sensing film;
wherein the substrate, the cover, and the sealed frame form a sealed space, the OLED device and the humidity sensing film are inside the sealed space, and another end of each of the testing wires stretches to an outside of the sealed space via the sealed frame for being electrically connected to a testing device.

2. The OLED panel of claim 1, wherein the humidity sensing film is manufactured with a conductive powder and a high molecular material having a characteristic of easily absorbing humidity to expand, and the conductive power is a carbon black powder.

3. The OLED panel of claim 1, wherein the substrate is a glass substrate, and the sealed frame is manufactured with a fit glue or a UV glue.

4. A manufacturing method for manufacturing an organic light emitting diode (OLED) panel, the manufacturing method comprising:
providing a cover;
forming a testing wire on the cover;
spreading a frit glue on a position near an edge of the cover and performing a high-temperature baking on the fit glue to form a sealed frame, wherein one end of the testing wire is inside the sealed frame, and another end of the testing wire is outside the sealed frame;
forming a humidity sensing film inside the sealed frame on the cover and performing a low-temperature baking, wherein the humidity sensing film covers parts of the testing wire;
spreading a bonding glue on the sealed frame;
providing a substrate, wherein an OLED device is formed on the substrate; and
fixing the substrate and the cover by using the bonding glue and solidifying the sealed frame.

5. The manufacturing method of claim 4, wherein the humidity sensing film is manufactured with a conductive powder and a high molecular material having a characteristic of easily absorbing humidity to expand, the conductive power is a carbon black powder, and the bonding glue is a cofferdam glue.

6. A manufacturing method for manufacturing an organic light emitting diode (OLED) panel, the manufacturing method comprising:
providing a cover;
forming a testing wire on the cover;
forming a humidity sensing film on the cover and performing a low-temperature baking, wherein the humidity sensing film covers parts of the testing wire;
spreading a UV glue on a position near an edge of the cover to form a sealed frame, wherein the humidity sensing film is inside the sealed frame, one end of the testing wire is inside the sealed frame, and another end of the testing wire is outside the sealed frame;
providing a substrate, wherein an OLED device is formed on the substrate; and
fixing the substrate and the cover by using the UV glue and solidifying the sealed frame.

7. The manufacturing method of claim 6, wherein the humidity sensing film is manufactured with a conductive powder and a high molecular material having a characteristic of easily absorbing humidity to expand, and the conductive power is a carbon black powder.

8. A testing method for testing a packaging effect of an organic light emitting diode (OLED) panel, the testing method comprising:
providing an OLED panel, the OLED panel comprising a substrate, a cover positioned oppositely to the substrate, an OLED device positioned on the substrate, a humidity sensing film positioned on the cover, a sealed frame for adhering the substrate and the cover, a plurality of testing wires between the humidity sensing film and the cover, wherein one end of each of the testing wires is electrically connected to the humidity sensing film, wherein the substrate, the cover, and the sealed frame form a sealed space, the OLED device and the humidity sensing film are inside the sealed space, and another end of each of the testing wires stretches to an outside of the sealed space;
providing the testing device and electrically connecting the testing device to the another end of the testing wire such that the testing device is electrically connected to the humidity sensing film; and
measuring a conductivity of the humidity sensing film and comparing the measured conductivity with a predetermined standard conductivity to determine the packaging effect.

9. The testing method of claim 8, wherein the humidity sensing film is manufactured with a conductive powder and a high molecular material having a characteristic of easily absorbing humidity to expand, and the conductive power is a carbon black powder.

10. The testing method of claim 8, wherein the standard conductivity is corresponding to a conductivity of the humidity sensing film under the condition that the humidity sensing film contains 1000 ppm water and 10⁶ ppm oxygen, and if the measured conductivity is larger than or equal to the standard conductivity, then the packaging effect is determined as qualified, otherwise, the packaging effect is determined as unqualified.
